(19) United States
(12) Patent Application Publication
(10) Pub. No.: US 2008/0153300 A1
(43) Pub. Date: Jun. 26, 2008

(54) Method for forming fine pattern of semiconductor device

(75) Inventor: Cheol Kyu Bok, Icheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/806,172

(22) Filed: May 30, 2007

(30) Foreign Application Priority Data
Dec. 20, 2006 (KR) 10-2006-0130999

(51) Int. Cl. H01L 21/311

(52) U.S. Cl. 438/703; 257/E21.249

(57) ABSTRACT

A method for forming a fine pattern of a semiconductor device comprises the steps of: preparing a semiconductor substrate including an underlying layer, an insulating film, a bottom anti-reflection film, and a positive photoresist film sequentially; patterning the positive photoresist film to form a positive photoresist pattern; forming a negative photoresist film over the resulting structure including the positive photoresist pattern; patterning the negative photoresist film to form a negative photoresist pattern between the positive photoresist pattern; patterning the insulating film and the bottom anti-reflection film with the positive photoresist pattern and the negative photoresist pattern as an etching mask to form an insulating film pattern; and patterning the underlying layer with the insulating film pattern as an etching mask.

### CROSS-REFERENCES TO RELATED APPLICATIONS

The present application claims priority to Korean patent application number 10-2006-0130999, filed on Dec. 30, 2006, which is incorporated herein by reference in its entirety.

### BACKGROUND

The present invention generally relates to semiconductor fabrication technologies and, more particularly, to a method for forming a fine pattern of a semiconductor device.

Recently, the development of photolithography technologies has enabled the growth of electronic industries. In order to improve the scale of integration of semiconductor devices, photolithography technologies for forming fine patterns have been developed.

A photolithography technology often includes an exposure technology using a chemically amplified Deep Ultra Violet (DUV) light source having a short wavelength such as ArF (193 nm) or VUV (157 nm), and a photoresist technology for applying a photoresist material suitable for the short wavelength.

Also, the photolithography technology includes a technology of forming a bottom anti-reflective coating layer in a lower part of a photoresist film in order to prevent scattered reflection generated from the lower layer of the photoresist film and to remove standing waves caused by changes in thickness of the photoresist film.

As a semiconductor device becomes smaller, it is important to control a gate critical dimension. Generally, data processing speed and therefore performance of a semiconductor device becomes higher as the gate critical dimension, that is, the line-width of the pattern, becomes smaller. A double exposure method for reducing the pattern line-width without developing any photoresist materials has been applied to a current process for producing a semiconductor device.

### SUMMARY OF THE INVENTION

Embodiments of the present invention is directed at providing a method for forming a fine pattern which includes etching a lower underlying layer with an etching mask of a first positive photoresist pattern and a second negative photoresist pattern, which are formed by a double exposure process.

According to one embodiment of the present invention, a method for forming a fine pattern of a semiconductor device comprises the steps of: preparing a semiconductor substrate on which a stack layer including an underlying layer and a positive photoresist film; patterning the positive photoresist film to form a positive photoresist pattern; forming a negative photoresist film over the positive photoresist pattern; patterning the negative photoresist film to form a negative photoresist pattern between the positive photoresist pattern; and patterning the underlying layer using the positive photoresist pattern and the negative photoresist pattern as an etching mask.

In another embodiment, a method for forming a fine pattern of a semiconductor device comprises the steps of: preparing a semiconductor substrate on which a stack layer including an underlying layer, an insulating film, a bottom anti-reflection film, and a positive photoresist film; patterning the positive photoresist film to form a positive photoresist pattern; forming a negative photoresist film over the positive photoresist pattern; patterning the negative photoresist film to form a negative photoresist pattern between the positive photoresist pattern; patterning the insulating film and the bottom anti-reflection film using the positive photoresist pattern and the negative photoresist pattern as an etching mask to form an insulating film pattern; and patterning the underlying layer using the insulating film pattern as an etching mask.

The positive photoresist patterns and the negative photoresist patterns are respectively formed by a given pitch (A), and the positive photoresist pattern and the negative photoresist pattern neighboring each other are formed by a pitch (1/2A).

### BRIEF DESCRIPTION OF THE DRAWINGS

FIGS. 1a through 1h are cross-sectional diagrams of a semiconductor device illustrating a method for forming a pattern of the semiconductor device.

FIGS. 2a through 2f are cross-sectional diagrams of a semiconductor device illustrating a method for forming a pattern of a semiconductor device consistent with the present invention.

### DETAILED DESCRIPTION

The present invention will be described in detail with reference to the accompanying drawings.

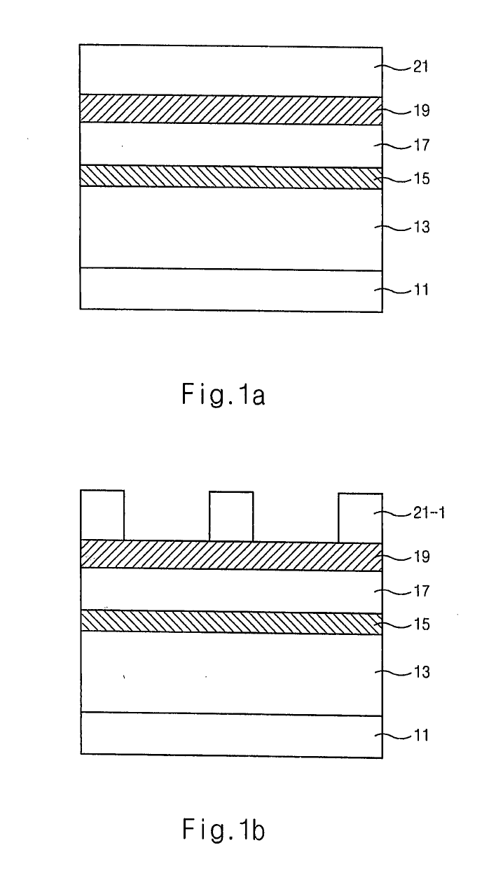

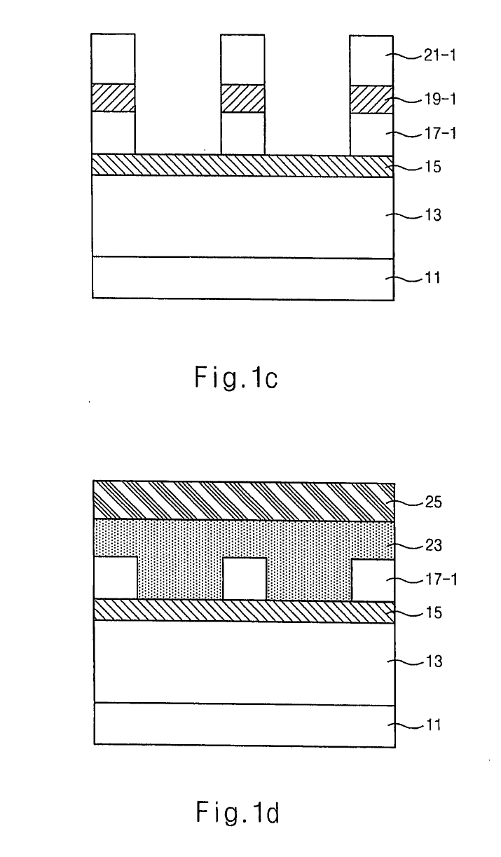

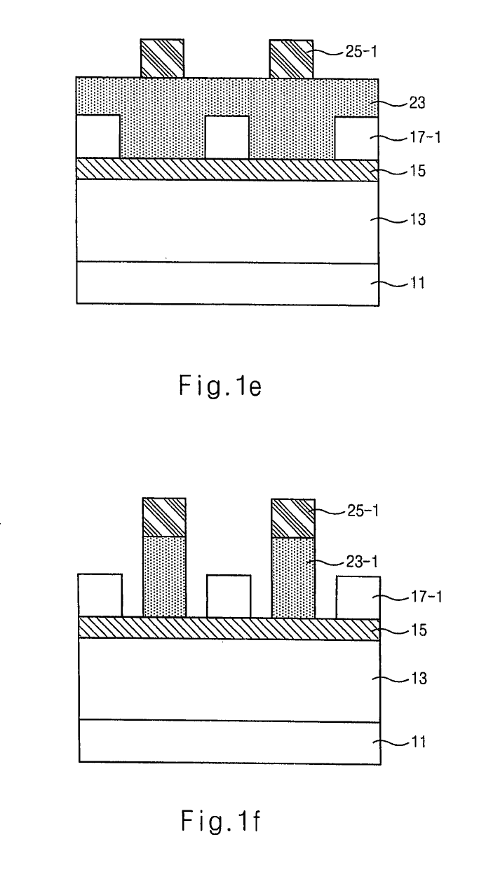

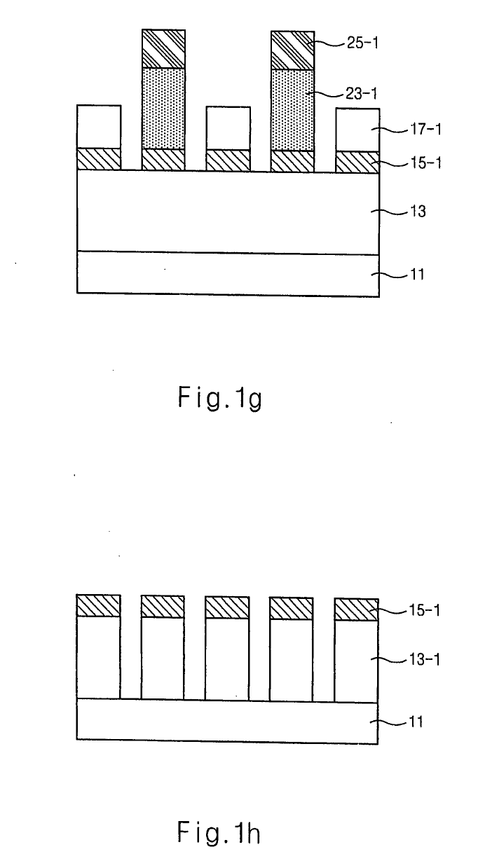

FIGS. 1a through 1h are cross-sectional diagrams of a semiconductor device illustrating a method for forming a pattern of the semiconductor device.

FIG. 1a shows a semiconductor substrate 11 including an underlying layer 13, an insulating film 15, a polysilicon layer 17, a first bottom anti-reflection film 19 and a first positive photoresist film 21, sequentially. Semiconductor substrate 11 may be prepared by any appropriate methods to form underlying layer 13, insulating film 15, polysilicon layer 17, first bottom anti-reflection film 19, and first positive photoresist film 21, in sequence. Other sequences, however, may also be used.

FIG. 1b shows a first photoresist pattern 21-1 obtained by performing a first patterning process on the first positive photoresist film 21.

FIG. 1c shows a first bottom anti-reflection pattern 19-1 and a polysilicon layer pattern 17-1 obtained by performing a sequential etching process on the first bottom anti-reflection film 19 and the polysilicon layer 17 with the first photoresist pattern 21-1 as an etching mask.

FIG. 1d shows a structure where the first photoresist pattern 21-1 and the first bottom anti-reflection pattern 19-1 are removed to expose the polysilicon layer pattern 17-1 and a second bottom anti-reflection film 23 and a second positive photoresist film 25 are formed over the resulting structure including the polysilicon layer pattern 17-1.

FIG. 1e shows a second positive photoresist pattern 25-1 which is obtained by performing a second patterning process on the second positive photoresist film 25.

FIG. 1f shows a structure deposited a second bottom anti-reflection pattern 23-1 and the second photoresist pattern 25-1 which is obtained by patterning the second bottom anti-reflection film 23 with the second photoresist pattern 25-1 as an etching mask. The polysilicon pattern 17-1 is also exposed.

FIG. 1g shows a structure where the insulating film 15 is etched with the deposition structure including the exposed polysilicon layer pattern 17-1, the second bottom anti-reflection pattern 23-1 and the second photoresist pattern 25-1 as an etching mask to obtain an insulating film pattern 15-1.

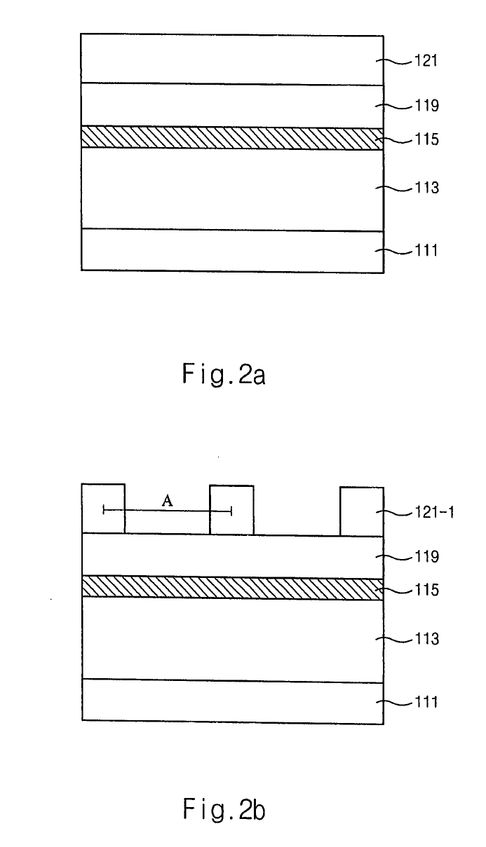

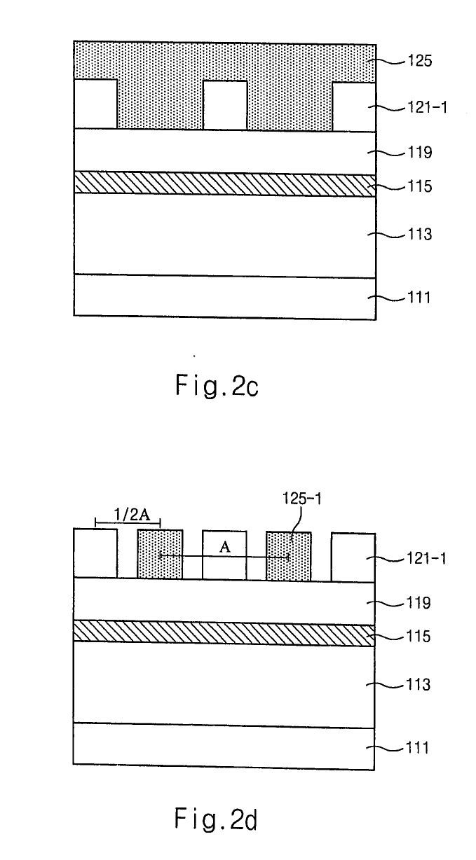

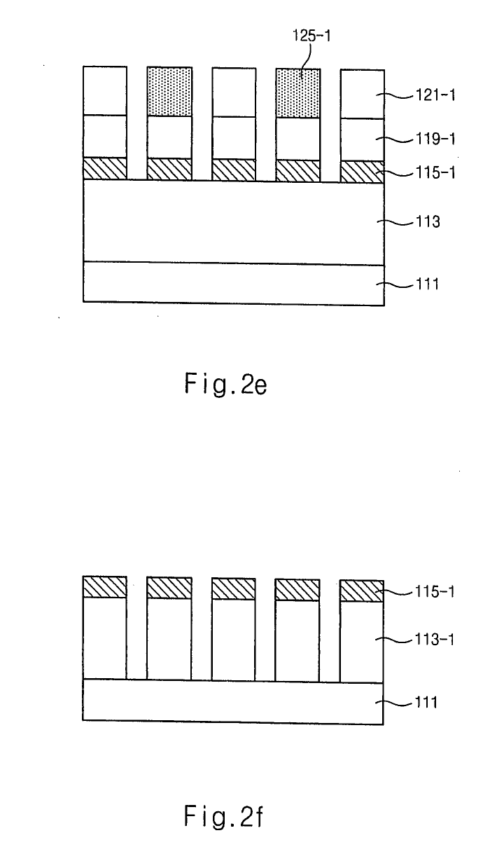

FIG. 1h shows a structure where the polysilicon layer pattern 17-1, the second bottom anti-reflection pattern 23-1 and the second photoresist pattern 25-1 are removed, and an underlying layer 13 is patterned until the semiconductor substrate 11 is exposed with the exposed insulating film pattern 15-1 as an etching mask to obtain an underlying layer pattern 13-1. Characteristics of the processes shown in FIGS. 1a-1h may be similar to those of structures shown in FIGS. 2a-2f, as described below in detail.

FIGS. 2a through 2f are cross-sectional diagrams of a semiconductor device illustrating a method for forming a pattern of the semiconductor device consistent with the present invention.

FIG. 2a shows a semiconductor substrate 111 including an underlying layer 113, an insulating film 115, a bottom anti-reflection film 119 and a positive photoresist film 121. Semiconductor substrate 11 may be prepared by any appropriate methods to form underlying layer 113, insulating film 115, bottom anti-reflection film 119, and positive photoresist film 121, sequentially. Another layer or layers of appropriate material may be added and other sequences may also be used.

In certain embodiments, the underlying layer 113 is deposited at a thickness ranging from 1500 to 2200 Å, preferably 2000 Å with an amorphous carbon.

The insulating film 115 is deposited on the underlying layer 113 at a thickness ranging from 350 to 450 Å, preferably 400 Å with a silicon oxy nitride (SiON) film, a silicon nitride film, a silicon oxide film or a stack thereof.

Any appropriate type of anti-reflection film used in photolithography processes may be used as the bottom anti-reflection film 119. In one embodiment, the anti-reflection film 119, for example, based on anti-reflection films produced by Dongjin Semichem Co., is deposited on the insulating film 115 at a thickness ranging from 300 to 350 Å, preferably 330 Å.

Any appropriate types of chemically amplified photoresist composition may be used to form the positive photoresist film 121. For example, the positive photoresist film 121 is formed using a positive photoresist composition including a photoacid generator, an organic solvent and a chemically amplified polymer. The photoacid generator is selected from the group consisting of: triphenyl sulfoniumtriplate, triphenyl sulfoniumnonaplate and combinations thereof. And the organic solvent is selected from the group consisting of: diethylene glycol, diethyl ether, cyclohexane and combinations thereof. Examples of the chemically amplified polymers that can be used include those disclosed in U.S. Pat. No. 5,750,680 (May 12, 1998), U.S. Pat. No. 6,051,678 (Apr. 18, 2000), U.S. Pat. No. 6,132,926 (Oct. 17, 2000), U.S. Pat. No. 6,143,463 (Nov. 7, 2000), U.S. Pat. No. 6,150,069 (Nov. 21, 2000), U.S. Pat. No. 6,180,316 B1 (Jan. 30, 2001), U.S. Pat. No. 6,225,020 B1 (May 1, 2001), U.S. Pat. No. 6,235,448 B1 (May 22, 2001) and U.S. Pat. No. 6,235,447 B1 (May 22, 2001). The chemically amplified polymer is selected from the group consisting of: a ROMA-type polymer including ring-open maleic anhydride as a polymerization repeating unit; a novolak polymer including a methacrylate or acrylate polymerization repeating unit; a norbornene polymer including the methacrylate or acrylate polymerization repeating unit, a cycloolefin polymerization repeating unit and a maleic anhydride polymerization repeating unit; and a hybrid type polymer including combinations thereof. More specifically, the chemically amplified polymer of positive photoresist film includes a base resin selected from the group consisting of: poly{4-[2-(4-hydroxyphenyl)-1,1,1,3,3,3-hexafluoropropyl]phenyl methacrylate/(1,1,1,3,3,3-hexafluoro-2-tert-butyl carboxylate)isopropyl methacrylate}; poly(maleic anhydride/4-fluorostylene/2,6-difluoro-α-methylbenzyl-5-norbornene-2-carboxylate); poly(N-methylmaleimide/hexa-fluorobutyl-5-norbornene-2-carboxylate/2,6-difluoro-α-methylbenzyl-5-norbornene-2-carboxylate); poly(N-t-butoxymaleimide/2,6-difluorostylene/2,6-difluoro-α-methylbenzyl-5-norbornene-2-carboxylate); poly(N-methylmaleimide/2,6-difluoro-α-methyl-benzyl-5-norbornene-2-carboxylate); poly(maleic anhydride/hexafluorobutyl-5-norbornene-2-carboxylate/2,6-difluoro-α-methylbenzylacrylate); poly(N-methylmaleimide/hexafluoro-butyl-5-norbornene-2-carboxylate/2,6-difluoro-α-methyl-benzylacrylate); poly(t-butyl bicycle[2.2.1]hept-5-en-2-carboxylate/2-hydroxyethyl bicyclo[2.2.1]hept-5-en-2-carboxylate/bicyclo[2.2.1]hept-5-en-2-carboxylic acid/maleic anhydride); poly(t-butyl bicyclo[2.2.1]hept-5-en-2-caryboxylate/2-hydroxyethyl bicyclo[2.2.2]oct-5-en-2-carboxylate/bicyclo[2.2.1]hept-5-en-2-carboxylic acid/maleic anhydride); poly(N-t-butoxymaleimide/hexafluoro-butyl-5-norbornene-2-carboxylate/2,6-difluoro-α-methyl benzylacrylate); and poly(N-(tertiary-butyl oxy-carbonyl)sis-4-cyclohexene-1,2-dicarboximide/3,3,4,4,5,5,6,6,6-nonafluoro-1-hexene/sis-4-cyclohexene-1,2-dicarboximide).

The positive photoresist film 121 is formed over bottom anti-reflection film 119 at a thickness ranging from 1000 to 2000 Å, preferably 1500 Å with HAS-4474 (produced by JSR Co.).

FIG. 2b shows a positive photoresist pattern 121-1 having a pitch A obtained by performing a first patterning process on the positive photoresist film 121.

The first patterning process includes a first exposure process performed with a light source selected from the group consisting of KrF, ArF, VUV, EUV, E-beam, X-ray and ion beam and with an exposure energy ranging from 0.1 to 100 mJ/cm², and a first developing process performed with a 2.38% tetramethyl ammonium hydroxide (TMAH) alkali solution. In one embodiment, the first patterning process is performed with a 1400i ArF Immersion scanner (produced by ASML Co.) in the first exposure process.

FIG. 2c shows a structure where a negative photoresist film 125 is formed over the resulting structure obtained from the first patterning process including the positive photoresist pattern 121-1 of FIG. 2b.

Any appropriate types of chemically amplified negative photoresist composition may be used to form the negative photoresist film 125. Examples of the negative photoresist composition that can be used include those disclosed in U.S. Pat. No. 5,541,036 (Jul. 30, 1996), U.S. Pat. No. 5,879,855 (Mar. 9, 1999), U.S. Pat. No. 6,074,801 (Jan. 13, 2000), U.S. Pat. No. 6,140,010 (Oct. 31, 2000), U.S. Pat. No. 6,800,415 (Oct. 5, 2004), U.S. Pat. No. 6,943,124 (Sep. 13, 2005) and U.S. Pat. No. 7,063,934 (Jan. 20. 2006). More specifically, the negative photoresist composition may comprise a photoacid generator, an organic solvent, a chemically amplified polymer, and melamine as a cross-linker of positive photoresist film. In certain embodiments, the photoacid generator, the organic solvent, and the chemically amplified polymer may be the same as those used in positive photoresist film 121.

The chemically amplified polymer for negative photoresist film 125 is a water-soluble negative photoresist polymer including a repeating unit represented by Formula 1. That is, the polymer is water-soluble because the repeating unit of Formula 1 includes a salt in a branched chain of a part d.

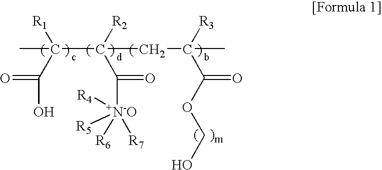

wherein R₁, R₂, R₃, R₄, R₅, R₆ and R₇ are individually selected from the group consisting of H, halogen elements such as F, Cl, Br or I, a C₁-C₁₀ alkyl group or CF₃; the relative ratio of b:c:d is 1-98 mol%:1-98 mol %:1-98 mol %, and m is an integer ranging from 1 to 10.

The negative photoresist film 125 may be formed by using negative photoresist film, such as TArF-NO23 negative photoresist (produced by TOKI Co.), coated over the resulting structure from the first patterning process at a thickness ranging from 1500 to 2000 Å, preferably 2000 Å.

FIG. 2d shows a negative photoresist pattern 125-1 having a pitch A obtained by performing a second patterning process on the negative photoresist film 125.

The second patterning process includes a second exposure process, and a second developing process. The second patterning process may be performed under the same conditions as those of the first patterning process. For example, the second exposure process may be performed with a light source selected from the group consisting of KrF, ArF, VUV, EUV, E-beam, X-ray and ion beam and with an exposure energy ranging from 0.1 to 100 mJ/cm², and the second developing process may be performed with a 2.38% tetramethyl ammonium hydroxide (TMAH) alkali solution. Although the positive photoresist pattern 121-1 formed during the second exposure process in the second patterning process is exposed by a light source, the positive photoresist pattern 121-1 is prevented from being dissolved in the alkali solution of the second developing process.

Through the above-described processes, the negative photoresist pattern 125-1 is formed between the positive photoresist patterns 121-1, as shown in FIG. 2d. That is, unremoved portion of the negative photoresist film 125 (the negative photoresist pattern 125-1) is positioned relative to unremoved portion of the positive photoresist film 121 (positive photoresist pattern 121-1) such that no overlapping, either on a same layer or on different layers of a semiconductor device, exists between the negative photoresist pattern 125-1 and the positive photoresist pattern 121-1. The negative photoresist pattern 125-1 may have a pitch A, and the positive photoresist pattern 121-1 and the negative photoresist pattern 125-1 may be aligned to have a pitch 1/2A between each other, as shown in FIG. 2d.

FIG. 2e shows a bottom anti-reflection pattern 119-1 and an insulating film pattern 115-1 which are obtained by performing an etching process on the bottom anti-reflection film 119 and the insulating film 115 with the positive photoresist pattern 121-1 and the negative photoresist pattern 125-1 as etching masks.

The etching process on the insulating film 115 is performed, for example, in a FLEX etching chamber (produced by Lam Co.) using a plasma etching gas employing a mixture gas of CF₄ 50 sccm, CF₃ 50 sccm and O₂ 7 sccm as a source gas under a pressure of 100 mT and a power of 200 W.

FIG. 2f shows an underlying layer pattern 113-1 obtained by removing the positive photoresist pattern 121-1 and the negative photoresist pattern 125-1 and performing a patterning process on the underlying layer 113 with the exposed insulating film pattern 115-1 as an etching mask.

The patterning process is performed, for example, using a plasma etching gas employing a mixture gas of CF₄ 90 sccm, CF₃ 30 sccm, O₂ 11 sccm and Ar 600 sccm as a source gas under a pressure of 160 mT and a power of 150 W.

According to the disclosed embodiments of the present invention, a bottom anti-reflection film may only need to be formed once, and a negative photoresist film may be formed without removing a previously formed positive photoresist pattern, thereby simplifying process steps in a semiconductor fabrication process.

Further, an underlying layer pattern having a uniform profile can be formed because a combination of a negative photoresist pattern and a positive photoresist pattern as an etching mask has a uniform thickness and a similar etching selectivity in an etching process performed on the underlying layer.

Therefore, a fine pattern can be formed by a double exposure process using positive and negative photoresist films without any new processing equipment or methods, thereby improving productivity and reducing manufacturing cost.

The above embodiments of the present invention are illustrative and not limitating. Various alternatives and equivalents are possible. The invention is not limited by the lithography steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for forming a fine pattern of a semiconductor device, the method comprising the steps of:
preparing a semiconductor substrate over which a stack layer including an underlying layer and a positive photoresist film;
patterning the positive photoresist film to form a positive photoresist pattern;
forming a negative photoresist film over the positive photoresist pattern;
patterning the negative photoresist film to form a negative photoresist pattern between the positive photoresist pattern; and
patterning the underlying layer using the positive photoresist pattern and the negative photoresist pattern as an etching mask.

2. The method according to claim 1, wherein the positive photoresist pattern is formed by a given pitch A, the negative photoresist pattern is formed by a pitch A, and the positive photoresist pattern and the negative photoresist pattern neighboring each other are formed by a pitch 1/2A.

3. The method according to claim 1, wherein the positive photoresist film is formed using a positive photoresist composition including a photoacid generator, an organic solvent and a chemically amplified polymer.

4. The method according to claim 3, wherein the photoacid generator is selected from the group consisting of triphenyl sulfoniumtriplate, triphenyl sulfoniumnonaplate and combinations thereof.

5. The method according to claim 3, wherein the organic solvent is selected from the group consisting of diethylene glycol, diethyl ether, cyclohexane and combinations thereof.

6. The method according to claim 3, wherein the chemically amplified polymer is selected from the group consisting of a ROMA-type polymer including ring-open maleic anhydride as a polymerization repeating unit; a novolak polymer including a methacrylate or acrylate polymerization repeating unit; a norbornene polymer including the methacrylate or acrylate polymerization repeating unit, a cycloolefin polymerization repeating unit and a maleic anhydride polymerization repeating unit; and a hybrid type polymer including combinations thereof.

7. The method according to claim 3, wherein the chemically amplified polymer includes a base resin selected from the group consisting of poly{4-[2-(4-hydroxyphenyl)-1,1,1,3,3,3-hexafluoropropyl]phenyl methacrylate/(1,1,1,3,3,3-hexafluoro-2-tert-butyl carboxylate)isopropyl methacrylate}; poly(maleic anhydride/4-fluorostylene/2,6-difluoro-α-methylbenzyl-5-norbornene-2-carboxylate); poly(N-methylmaleimide/hexa-fluorobutyl-5-norbornene-2-carboxylate/2,6-difluoro-α-methylbenzyl-5-norbornene-2-carboxylate); poly(N-t-butoxymaleimide/2,6-difluorostylene/2,6-difluoro-α-methylbenzyl-5-norbornene-2-carboxylate); poly(N-methylmaleimide/2,6-difluoro-α-methyl-benzyl-5-norbornene-2-carboxylate); poly(maleic anhydride/hexafluorobutyl-5-norbornene-2-carboxylate/2,6-difluoro-α-methylbenzylacrylate); poly(N-methylmaleimide/hexafluoro-butyl-5-norbornene-2-carboxylate/2,6-difluoro-α-methyl-benzylacrylate); poly(t-butyl bicycle[2.2.1]hept-5-en-2-carboxylate/2-hydroxyethyl bicyclo[2.2.1]hept-5-en-2-carboxylate/bicyclo[2.2.1]hept-5-en-2-carboxylic acid/maleic anhydride); poly(t-butyl bicyclo[2.2.1]hept-5-en-2-caryboxylate/2-hydroxyethyl bicyclo[2.2.2]oct-5-en-2-carboxylate/bicyclo[2.2.1]hept-5-en-2-carboxylic acid/maleic anhydride); poly(N-t-butoxymaleimide/hexafluoro-butyl-5-norbornene-2-carboxylate/2,6-difluoro-α-methyl benzylacrylate); and poly(N-(tertiary-butyl oxy-carbonyl)sis-4-cyclohexene-1,2-dicarboximide/3,3,4,4,5,5,6,6,6-nonafluoro-1-hexene/sis-4-cyclohexene-1,2-dicarboximide).

8. The method according to claim 1, wherein the negative photoresist film is formed of using a negative photoresist composition including a photoacid generator, an organic solvent, a cross-linker and a chemically amplified polymer.

9. The method according to claim 8, wherein the photoacid generator is selected from the group consisting of triphenyl sulfoniumtriplate, triphenyl sulfoniumnonaplate and combinations thereof.

10. The method according to claim 8, wherein the organic solvent is selected from the group consisting of diethylene glycol, diethyl ether, cyclohexane and combinations thereof.

11. The method according to claim 8, wherein the cross-linker is melamine.

12. The method according to claim 8, wherein the chemically amplified polymer is selected from the group consisting of a ROMA-type polymer including ring-open maleic anhydride as a polymerization repeating unit; a novolak polymer including a methacrylate or acrylate polymerization repeating unit; a norbornene polymer including the methacrylate or acrylate polymerization repeating unit, a cycloolefin polymerization repeating unit and a maleic anhydride polymerization repeating unit; and a hybrid type polymer including combinations thereof.

13. The method according to claim 8, wherein the chemically amplified polymer includes a base resin selected from the group consisting of: poly{4-[2-(4-hydroxyphenyl)-1,1,1,3,3,3-hexafluoropropyl]phenyl methacrylate/(1,1,1,3,3,3-hexafluoro-2-tert-butyl carboxylate)isopropyl methacrylate}; poly(maleic anhydride/4-fluorostylene/2,6-difluoro-α-methylbenzyl-5-norbornene-2-carboxylate); poly(N-methylmaleimide/hexa-fluorobutyl-5-norbornene-2-carboxylate/2,6-difluoro-α-methylbenzyl-5-norbornene-2-carboxylate); poly(N-t-butoxymaleimide/2,6-difluorostylene/2,6-difluoro-α-methylbenzyl-5-norbornene-2-carboxylate); poly(N-methylmaleimide/2,6-difluoro-α-methyl-benzyl-5-norbornene-2-carboxylate); poly(maleic anhydride/hexafluorobutyl-5-norbornene-2-carboxylate/2,6-difluoro-α-methylbenzylacrylate); poly(N-methylmaleimide/hexafluoro-butyl-5-norbornene-2-carboxylate/2,6-difluoro-α-methyl-benzylacrylate); poly(t-butyl bicycle[2.2.1]hept-5-en-2-carboxylate/2-hydroxyethyl bicyclo[2.2.1]hept-5-en-2-carboxylate/bicyclo[2.2.1]hept-5-en-2-carboxylic acid/maleic anhydride); poly(t-butyl bicyclo[2.2.1]hept-5-en-2-caryboxylate/2-hydroxyethyl bicyclo[2.2.2]oct-5-en-2-carboxylate/bicyclo[2.2.1]hept-5-en-2-carboxylic acid/maleic anhydride); poly(N-t-butoxymaleimide/hexafluoro-butyl-5-norbornene-2-carboxylate/2,6-difluoro-α-methyl benzylacrylate); and poly(N-(tertiary-butyl oxy-carbonyl)sis-4-cyclohexene-1,2-dicarboximide/3,3,4,4,5,5,6,6,6-nonafluoro-1-hexene/sis-4-cyclohexene-1,2-dicarboximide).

14. The method according to claim 8, wherein the chemically amplified polymer is a water-soluble negative photoresist polymer.

15. The method according to claim 14, wherein the water-soluble negative photoresist polymer comprises a base resin having a repeating unit represented by Formula 1: 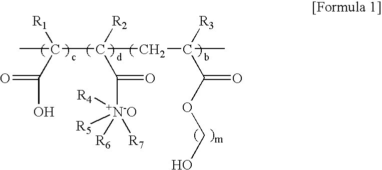
wherein R₁, R₂, R₃, R₄, R₅, R₆ and R₇ are selected from the group consisting of H, a halogen element, a C₁-C₁₀ alkyl group and CF₃;
the relative ratio of b:c:d is 1-98 mol %:1-98 mol %:1-98 mol %; and
m is an integer ranging from 1 to 10.

16. The method according to claim 1, wherein the first and second patterning process on the positive and negative photoresist film are performed under the same conditions.

17. A method for forming a fine pattern of a semiconductor device, the method comprising the steps of:
preparing a semiconductor substrate over which a stack layer including an underlying layer, an insulating film, a bottom anti-reflection film, and a positive photoresist film;
patterning the positive photoresist film to form a positive photoresist pattern;
forming a negative photoresist film over the positive photoresist pattern;
patterning the negative photoresist film to form a negative photoresist pattern between the positive photoresist pattern;
patterning the insulating film and the bottom anti-reflection film using the positive photoresist pattern and the negative photoresist pattern as an etching mask to form an insulating film pattern; and
patterning the underlying layer using the insulating film pattern as an etching mask.

18. The method according to claim 17, wherein the positive photoresist pattern is formed by a given pitch A,
the negative photoresist pattern is formed by a pitch A, and
the positive photoresist pattern and the negative photoresist pattern neighboring each other are formed by a pitch 1/2A.

19. The method according to claim 17, wherein the insulating film is formed of a silicon oxy nitride (SiON) film, a silicon nitride film, a silicon oxide film or a stack thereof.

20. The method according to claim 17, wherein the patterning process of the insulating film is performed using a plasma etching gas employing a mixture gas including CF₄, CF₃, O₂ and Ar as a source gas.
